(19) United States
(12) Patent Application Publication
(10) Pub. No.: US 2008/0030943 A1
(43) Pub. Date: Feb. 7, 2008

(54) Memory module having improved arrangement of discrete devices

(76) Inventors: Kyoung-sun Kim, Uijeongbu-si (KR); Sung-joo Park, Anyang-si (KR); Jung-joon Lee, Seoul (KR); Jea-eun Lee, Seoul (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/708,591

(22) Filed: Feb. 21, 2007

(30) Foreign Application Priority Data
Aug. 4, 2006 (KR) 2006-0073664

(51) Int. Cl. H05K 1/14

(52) U.S. Cl. 361/684

(57) ABSTRACT

Embodiments of the invention provide memory module having an improved arrangement of discrete devices. In one embodiment, the invention provides a memory module comprising a board; a plurality of tabs disposed adjacent to a first edge of the board and disposed on a first surface of the board; and a memory pad region disposed on the first surface and comprising memory chip pads, wherein each memory chip pad is electrically connected to at least one of the tabs. The memory module further comprises discrete devices corresponding to the memory pad region, wherein the discrete devices corresponding to the memory pad region are disposed on only one side of the memory pad region. In the memory module, each of the discrete devices is electrically connected to at least one of the tabs and at least one of the memory chip pads.

### BACKGROUND

1. Field of the Invention

Embodiments of the invention relate to a semiconductor device. In particular, embodiments of the invention relate to memory module having an improved arrangement of discrete devices.

This application claims priority to Korean Patent Application No. 2006-0073664, filed Aug. 4, 2006, the subject matter of which is hereby incorporated by reference in its entirety.

2. Description of the Related Art

Various electronic systems such as personal computers (PCs), system servers, and communication devices use memory modules to store data. A memory module comprises memory chips and discrete devices mounted on a printed circuit board (PCB) comprising tabs for electrically connecting the PCB with an external connector.

A memory chip of the memory module may be a volatile memory device such as Dynamic Random Access Memory (DRAM) or Static RAM (SRAM), and each discrete device may be a device selected from the group consisting of a resistor, a capacitor, an inductor, a register, a programmable device, and a non-volatile memory device. The discrete devices distribute external signals applied to the tabs to the memory chips for the storage of data, and data stored in the memory chips can be read out through the discrete devices.

FIG. 1 is a plan view of a conventional memory module. Referring to FIG. 1, the conventional memory module has memory chips 15 and discrete devices 17 attached to a board 11 (i.e., a main body of a board 11). In addition, tabs 13 are disposed at a first edge of board 11. The memory module of FIG. 1 comprises a PCB comprising board 11 and tabs 13.

A multi-layered board structure comprising of a four- to eight-layered board is widely used as board 11. Tabs 13 can be electrically connected to memory chips 15 and discrete devices 17 through interconnections formed within board 11. In addition, tabs 13 electrically connect memory chips 15 and discrete devices 17 to an external device.

Memory chips 15 are arranged in a line along a longitudinal axis of board 11 (i.e., an axis that is substantially parallel with the first edge of board 11). Each discrete device 17 corresponds to one of memory chips 15, and, as shown in FIG. 1, for each memory chip 15, the discrete devices 17 that correspond to that memory chip 15 are arranged around that memory chip 15. However, the sizes of memory chips 15 may vary in accordance with the degree of integration and the storage capacity of memory chips 15. For example, the area of a bottom surface of a large-capacity memory chip 15′ may be larger than the area of the bottom surface of a memory chip 15. In that case, it may not be possible to mount a large-capacity memory chip 15′ on the board 11 because of the arrangement of discrete devices 17.

In the conventional memory module, when a large-capacity memory chip 15′ needs to be mounted on board 11, the positions of discrete devices 17 should be changed. That is, the conventional memory module may require a PCB of a different size depending on the respective sizes of the memory chips 15 that will be mounted on the PCB of the memory module.

Another method of forming a memory module is disclosed in Japanese Laid-Open Patent Publication No. 2005-251971 to Katsuaki et al., which is hereby incorporated by reference in its entirety. Katsuaki et al. provide a method of mounting memory chips having different specifications from one another on a PCB having a predetermined length, and provide a memory module fabricated using the mounting method. However, a memory module requires discrete devices such as resistors, capacitors, and registers, and the discrete devices may limit an efficient arrangement of memory chips on the memory module.

Thus, an arrangement of discrete devices and memory chips on a memory module that allows larger memory chips 15 to be mounted on a PCB without changing the size of the PCB is required.

### SUMMARY OF THE INVENTION

Embodiments of the invention provide a memory module having an arrangement of memory chips and discrete devices that allows memory chips having various and extended sizes to be mounted on a PCB without changing the overall size of the PCB.

In one embodiment, the invention provides a memory module comprising a board; a plurality of tabs disposed adjacent to a first edge of the board and disposed on a first surface of the board; and a memory pad region disposed on the first surface and comprising memory chip pads, wherein each memory chip pad is electrically connected to at least one of the tabs. The memory module further comprises discrete devices corresponding to the memory pad region, wherein the discrete devices corresponding to the memory pad region are disposed on only one side of the memory pad region. In the memory module, each of the discrete devices is electrically connected to at least one of the tabs and at least one of the memory chip pads.

In another embodiment, the invention provides a memory module comprising a board; a plurality of tabs disposed adjacent to a first edge of the board and disposed on a first surface of the board; and a plurality of memory pad regions disposed on the first surface and separated from one another along a first axis substantially parallel to the first edge of the board, wherein each memory pad region comprises memory chip pads and each memory chip pad is electrically connected to at least one of the tabs. The memory module further comprises a plurality of groups of discrete devices, wherein each group of discrete devices corresponds to one of the memory pad regions, and, for each of at least one of the memory pad regions, the discrete devices of the group of discrete devices corresponding to the memory pad region are disposed on only one side of the memory pad region. In the memory module, each of the discrete devices is electrically connected to at least one of the tabs and at least on of the memory chip pads.

In yet another embodiment, the invention provides a memory module comprising a board; a plurality of first tabs disposed adjacent to a first edge of the board and disposed on a first surface of the board; and a plurality of second tabs disposed adjacent to the first edge of the board and disposed on a second surface of the board opposite the first surface. The memory module further comprises a plurality of first memory pad regions disposed on the first surface and separated from one another along a first axis substantially parallel to the first edge of the board, wherein each first memory pad region comprises first memory chip pads and each first memory chip pad is electrically connected to at least one of the first tabs; a plurality of second memory pad regions disposed on the second surface; and a plurality of groups of first discrete devices disposed on the first surface, wherein each group of first discrete devices correspond to one of the first memory pad regions, and, for each of at least one of the first memory pad regions, the first discrete devices of the group of first discrete devices corresponding to the first memory pad region is disposed on only one side of the first memory pad region. The memory module still further comprises a plurality of groups of second discrete devices disposed on the second surface. In the memory module, each of the first discrete devices is electrically connected to at least one of the first tabs and at least one of the first memory chip pads.

### BRIEF DESCRIPTION OF THE DRAWINGS

Embodiments of the invention will be illustrated herein with reference to the accompanying drawings, in which like reference symbols indicate like or similar elements throughout. In addition, the drawings are not necessarily to scale. In the drawings:

FIG. 1 is a plan view showing a conventional memory module;

FIG. 2 is a perspective view of a mounted memory module in accordance with an embodiment of the invention;

FIG. 3 is a plan view showing a memory module in accordance with an embodiment of the invention;

FIG. 4 is a plan view of a region E of a PCB of FIG. 3;

FIG. 5 is a cross-sectional view of the memory module of FIG. 3 taken along a line I-I′ of FIG. 3;

FIGS. 6 and 7 are plan views of rear surfaces of memory chips used in a memory module in accordance with embodiments of the invention;

FIGS. 8 to 13 are plan views of memory modules in accordance with other embodiments of the invention;

FIG. 14 is a cross-sectional view of a memory module in accordance with yet another embodiment of the invention;

FIG. 15 is a cross-sectional view of the memory module of FIG. 8 taken along a line II-II′ of FIG. 8; and,

FIG. 16 is a cross-sectional view of a memory module in accordance with still other embodiment of the invention.

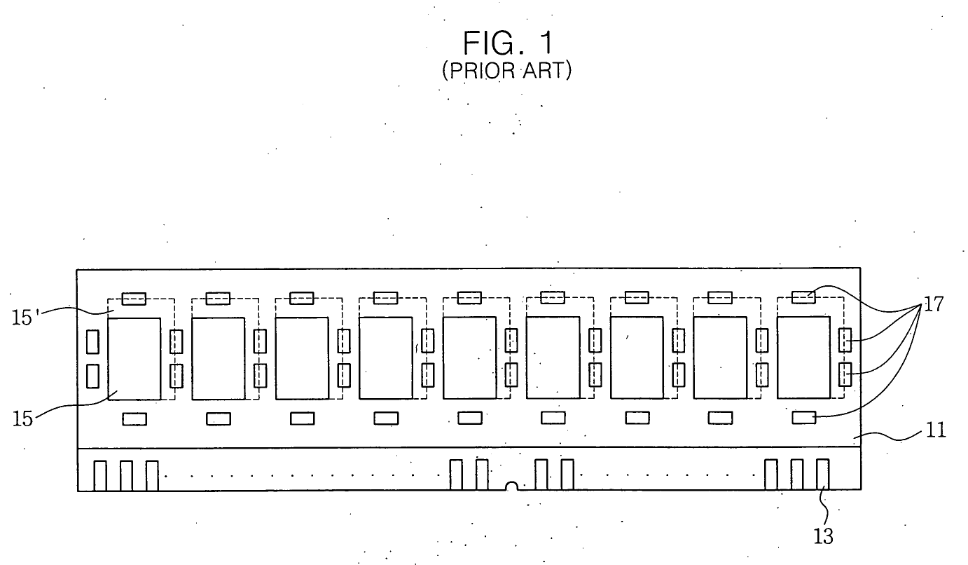

### DESCRIPTION OF EMBODIMENTS

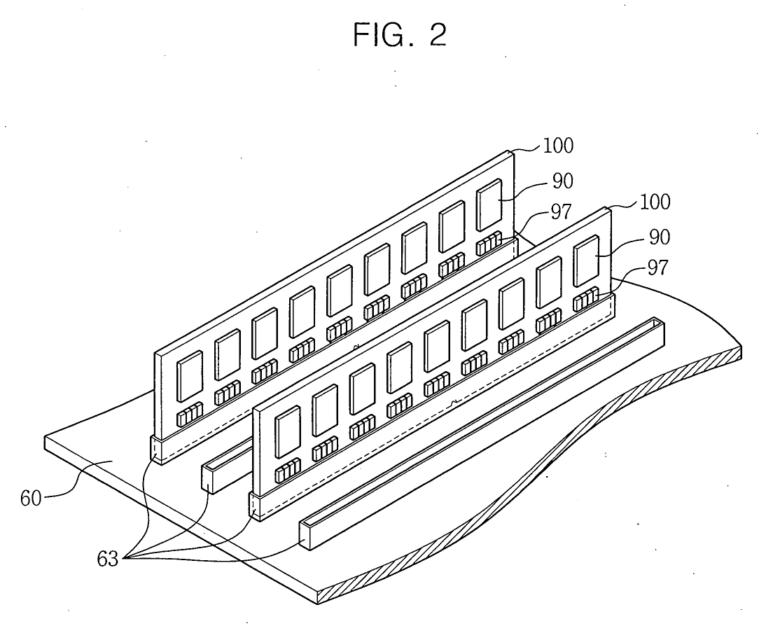

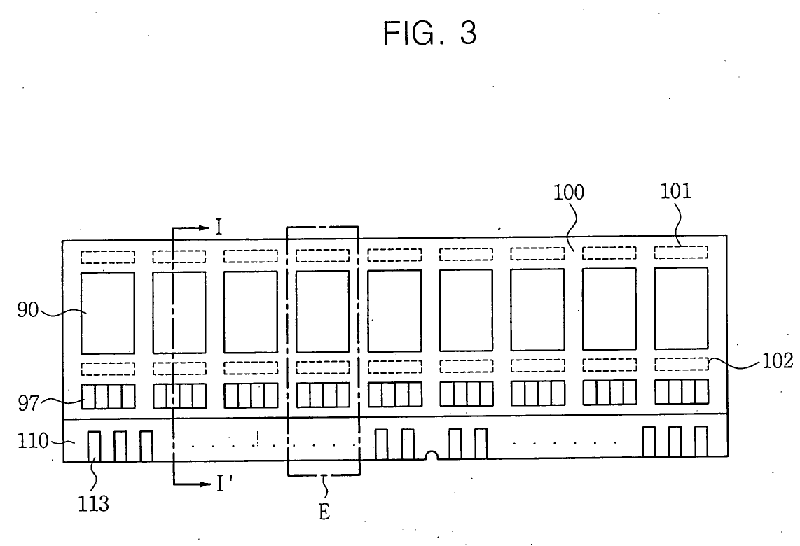

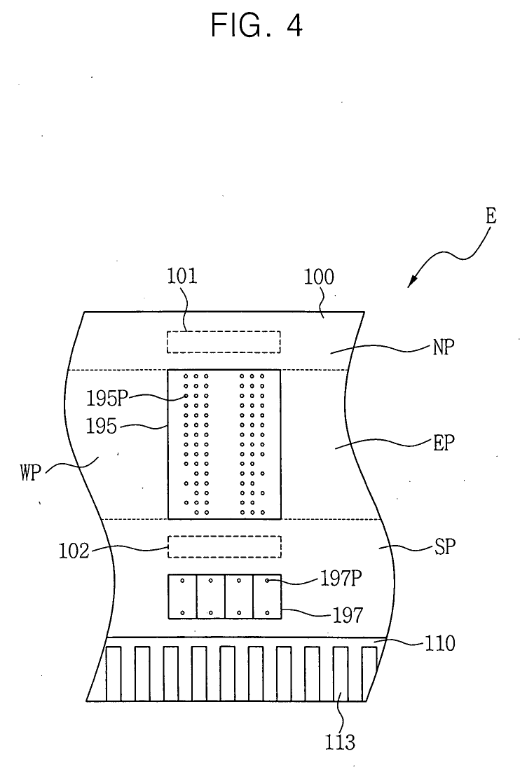

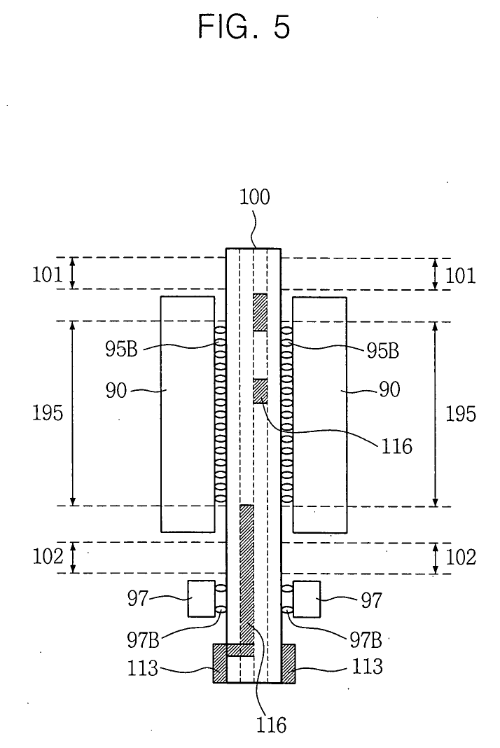

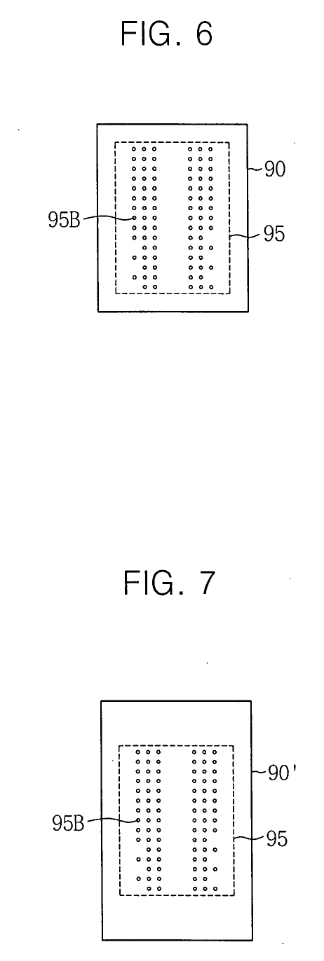

FIG. 2 is a perspective view of a mounted memory module in accordance with an embodiment of the invention, and FIG. 3 is a plan view showing the memory module of FIG. 2. FIG. 4 is a plan view of a region E of a PCB of FIG. 3, and FIG. 5 is a cross-sectional view of the memory module of FIG. 3 taken along a line I-I′ of FIG. 3. In addition, FIGS. 6 and 7 are plan views of rear surfaces of memory chips used in a memory module in accordance with embodiments of the invention.

In the embodiment illustrated in FIGS. 2 to 6, and referring to FIG. 2, a memory module comprises a board 100 (i.e., a main body of a board 100), memory chips 90, and discrete devices 97. As illustrated in FIG. 2, the memory module may be mounted in a socket 63 and electrically connected to an external device 60.

In various electronic systems such as PCs, system severs, or communication devices, the memory module may be used as a data storage device. For example, the external device 60 may be a main board of a PC, and a plurality of sockets 63 may be disposed on the main board. The external device 60 may store data in and read data from the memory module through sockets 63.

In the embodiment illustrated in FIGS. 2 to 6, board 100 is a thin board, and memory chips 90 are disposed in a line along a longitudinal axis of board 100 (i.e., along an axis that is substantially parallel to a first edge of board 100). In addition, at least one of the memory chips 90 may be a volatile memory device such as a DRAM device or an SRAM device. Additionally, board 100 has a thickness suitable for board 100 to be inserted into a socket 63.

Also in the embodiment illustrated in FIGS. 2 to 6, discrete devices 97 are divided into groups, wherein each group of discrete devices 97 corresponds to one of memory chips 90. For each memory chip 90, the discrete devices 97 of the group of discrete devices 97 that corresponds to the memory chip 90 is disposed on only one side of the memory chip 90. Each of discrete devices 97 may be a device selected from the group consisting of a resistor, a capacitor, an inductor, a register, a programmable device, and a non-volatile memory device. Also, discrete devices 97 may be adapted to distribute data that is input to memory chips 90 and data that is output from memory chips 90.

Referring to FIG. 3, a first tab region 110 is disposed adjacent to a first edge of board 100 and is disposed on a first surface of board 100. Additionally, first tab region 110 comprises a plurality of tabs 113, which are disposed on the first surface of board 100 and adjacent to the first edge of board 100. In addition, memory chips 90 are mounted in a line along the longitudinal axis of board 100 (i.e., an axis substantially parallel to the first edge of board 100), and are mounted on the first surface of board 100. In addition, each group of discrete devices 97 is disposed between a memory chip 90 and first tab region 110, and discrete devices 97 are electrically connected to memory chips 90 and tabs 113.

Additionally in the embodiment illustrated in FIGS. 2 to 6, board 100 is a relatively thin board, additional tabs 113 are disposed on a second surface of board 100 opposite the first surface, and first tab region 110 may be inserted into one of sockets 63. In addition, tabs 113 may be layers formed from a conductive material such as copper. In that case, tabs 113 may electrically connect memory chips 90 to external device 60.

Also in the embodiment illustrated in FIGS. 2 to 6, referring to FIG. 3, first buffer regions 101 are disposed adjacent to a second edge of board 100 opposite the first edge of board 100. First buffer regions 101 are adapted to separate (i.e., space) memory chips 90 from the second edge of board 100. In addition, second buffer regions 102 are disposed between each memory chip 90 and its corresponding group of discrete devices 97. Each second buffer region 102 is adapted to separate one of the memory chips 90 from its corresponding group of discrete devices 97. In addition, additional memory chips 90 and discrete devices 97 are mounted on the second surface of board 100.

In accordance with the embodiment illustrated in FIGS. 2 to 6, referring to FIG. 4, a memory pad region 195 is disposed on the first surface of board 100, so memory pad region 195 is disposed on the same surface as first tab region 110. The size and shape of memory pad region 195 corresponds to a terminal region 95 (see FIG. 6) of memory chip 90. In addition, memory chip pads 195P arranged to correspond to a plurality of terminals disposed in terminal region 95 of a memory chip 90 are disposed within memory pad region 195. Memory chip pads 195P may be layers formed from a conductive material such as copper. Memory chip pads 195P may be electrically connected to tabs 113.

As an example, 84 memory chip pads 195P may be disposed within memory pad region 195. In addition, memory pad region 195 may comprise more memory chip pads 195P than the number of terminals disposed in terminal region 95 of a memory chip 90.

Referring to FIG. 4, memory pad region 195 is separated from tab region 110. Region E of the first surface of board 100, which is shown in FIG. 4, may be divided into upper, lower, right, and left regions NP, SP, EP, and WP around memory pad region 195. That is, lower region SP is disposed between memory pad region 195 and first tab region 110, and upper region NP is disposed between the second edge of main body 100 and memory pad region 195. In addition, left region WP is disposed at the left side of memory pad region 195 between upper region NP and lower region SP, and right region EP is disposed at the right side of memory pad region 195 between upper region NP and lower region SP.

Still referring to FIG. 4, a discrete device pad region 197 corresponds to memory pad region 195 and is disposed between memory pad region 195 and first tab region 110. That is, discrete device pad region 197, which corresponds to memory pad region 195, is disposed on only one side of memory pad region 195. Discrete device pads 197P corresponding to discrete devices 97 are disposed in discrete device pad region 197. Discrete device pads 197P may be layers formed from a conductive material such as copper. Discrete device pads 197P may be electrically connected to memory chip pads 195P and tabs 113.

In addition, a first buffer region 101 is disposed in upper region NP. First buffer region 101 does not comprise discrete device pads 197P or memory chip pads 195P. That is, first buffer region 101 is adapted to separate memory pad region 195 apart from the second edge of board 100.

A second buffer region 102 is disposed between memory pad region 195 and discrete device pad region 197. That is, second buffer region 102 is disposed in lower region SP. Second buffer region 102 is adapted to separate memory pad region 195 from discrete device pad region 197.

In the embodiment illustrated in FIGS. 2 to 5, the illustrated memory module comprises a PCB comprising a board 100, tabs 113, memory chip pads 195P, and discrete device pads 197P. Memory chip 90 may be mounted on memory pad region 195. That is, memory chip 90 comprising terminal region 95 corresponding to memory pad region 195 may be mounted on the PCB. In addition, discrete devices 97 may be mounted on discrete device pad region 197.

Referring to FIGS. 3 and 4, memory pad region 195 is separated from the second edge of board 100 by first buffer region 101. In addition, memory pad region 195 is separated from discrete devices 97 of the group of discrete devices 97 that corresponds to memory pad region 195 (and is separated from discrete device pad region 197) by second buffer region 102. Accordingly, a memory chip 90 can be mounted on the PCB even when the area of the bottom of the memory chip 90 is larger than the area of memory pad region 195. That is, a PCB comprising first buffer region 101 and second buffer region 102 can provide a margin sufficient for some memory chips 90 with different sizes to be mounted on the PCB.

Referring to FIG. 5, in the embodiment illustrated in FIGS. 2 to 6, board 100 is formed by laminating four thin boards. In addition, board 100 comprises internal interconnections 116, which act to electrically connect tabs 113, memory chips 90, and discrete devices 97. Internal interconnections 116 may be layers formed from a conductive material such as copper. The memory module of the embodiment illustrated in FIGS. 2 to 6 comprises a PCB comprising board 100, tabs 113, memory chip pads 195P (see FIG. 4), discrete device pads 197P (see FIG. 4), and internal interconnections 116.

Discrete devices 97 are attached to discrete device pads 197P (see FIG. 4) through discrete device terminals 97B. As a result, discrete devices 97 are disposed adjacent to tabs 113. Discrete device terminals 97B may be conductive adhesive materials such as solder balls. In addition, discrete devices 97 may be electrically connected to tabs 113 and memory chips 90 through internal interconnections 116.

Memory chips 90 may be attached to the PCB by attaching individual memory chips 90 to memory chip pads 195P (see FIG. 4) through a plurality of terminals 95B disposed in the terminal region 95 of each individual memory chip 90. Terminals 95B may be conductive adhesive materials such as solder balls. Because memory chips 90 are attached to memory chip pads 195P, memory chips 90 are disposed over memory pad regions 195, respectively. Memory chips 90 may be electrically connected to tabs 113 and discrete devices 97 through internal interconnections 116.

Still referring to FIG. 5, first buffer region 101 is disposed adjacent to the second edge of tab region 110. Second buffer region 102 is disposed between memory pad region 195 and discrete devices 97. That is, memory chip 90 is separated from the second edge of board 100 by first buffer region 101. In addition, memory chip 90 is separated from discrete devices 97 by second buffer region 102. Accordingly, it may be possible to mount a memory chip 90 on the PCB even when the area of the bottom of the memory chip 90 is greater than the area of memory pad region 195. That is, a PCB comprising first buffer region 101 and second buffer region 102 may have a sufficient margin to allow memory chips 90 having various sizes to be mounted on the PCB.

Referring to FIG. 5, in the embodiment illustrated in FIGS. 2 to 6, memory chips 90 and discrete devices 97 are disposed on both the first and second surfaces of board 100. Tabs 113 are also disposed on both surfaces of board 100. When memory chips 90 are disposed on both surfaces of board 100, the arrangement of memory chips 90 on the first surface of board 100 and the arrangement of memory chips 90 on the second surface of board 100 may be symmetrical with respect to a plane passing through the center of board 100 and substantially parallel to the first and second surfaces. Alternatively, the arrangement of memory chips 90 on the first surface of board 100 and the arrangement of memory chips 90 on the second surface of board 100 may be asymmetrical with respect to the previously described plane.

Referring to FIG. 6, memory chip 90 comprises a terminal region 95, and terminals 95B are disposed within terminal region 95. Terminals 95B may be conductive adhesive materials such as solder balls. For example, terminals 95B may be 84 solder balls that are arranged in six columns. The area of the bottom of memory chip 90 may be larger than the area of terminal region 95, and terminal region 95 may be disposed on the bottom surface of memory chip 90.

Referring to FIG. 7, the area of the bottom of a large-capacity memory chip 90′ may be larger than the area of the bottom of memory chip 90. However, as illustrated in FIG. 7, terminal region 95 of large-capacity memory chip 90′ may be the same size (i.e., have the same area) as terminal region 95 of memory chip 90.

In the embodiment illustrated in FIGS. 2 to 6, the memory module comprises memory chips 90 and discrete devices 97 mounted on a PCB. The PCB comprises board 100, tabs 113, internal interconnections 116, memory chip pads 195P, memory pad regions 195, discrete device pads 197P, and discrete device pad regions 197.

On each of the first and second surfaces of board 100, discrete device pads 197P are disposed between tabs 113 and memory chip pads 195P (i.e., memory pad regions 195), and when discrete devices 97 are mounted on discrete device pads 197P, groups of discrete devices 97 are disposed between tabs 113 and corresponding memory pad regions 195, respectively. In addition, each group of discrete devices 97 corresponds to one memory pad region 195, and the discrete devices 97 of the group of discrete devices that corresponds to a memory pad region 195 is disposed on only one side of that memory pad region 195. Also, first buffer region 101 and second buffer region 102 are disposed on the surface of board 100, and discrete device pads 197P are not disposed on buffer regions 101 and 102. Accordingly, it may be possible to mount memory chips 90 having various sizes onto the PCB. That is, it may be possible to mount large-capacity memory chip 90′ onto the PCB when terminal region 95 of large-capacity memory chip 90′ corresponds to memory pad region 195.

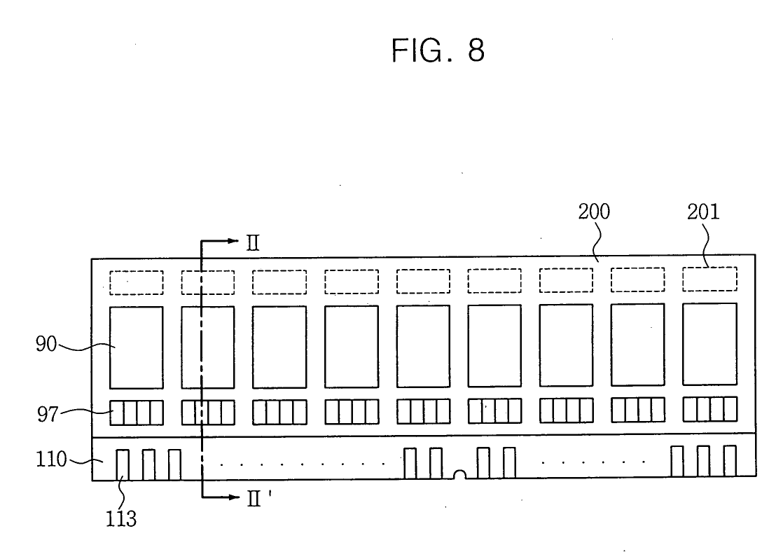

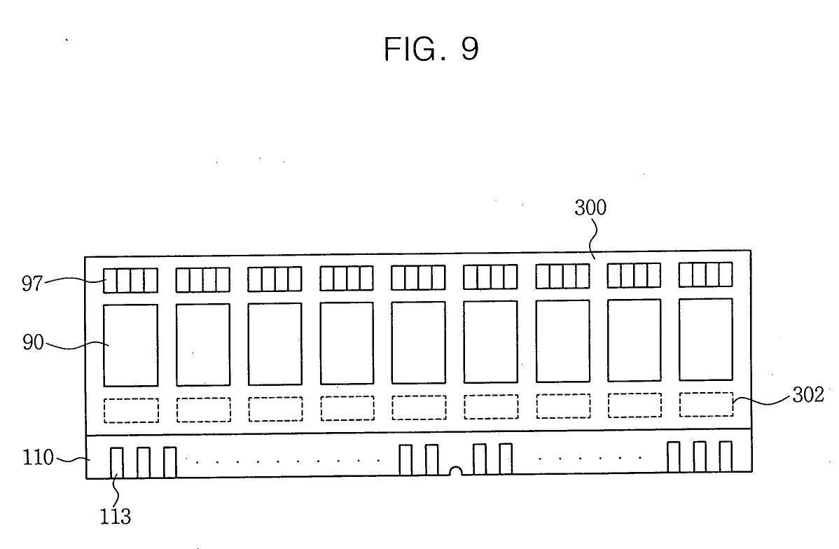

Various embodiments of the invention will now be described with reference to FIGS. 8 through 13. Each of FIGS. 8 to 13 illustrates a memory module in accordance with an embodiment of the invention. Each of the memory modules illustrated in FIGS. 8 through 13 comprises a board; memory chips 90; discrete devices 97; and a tab region 110 comprising a plurality of tabs 113, disposed adjacent to a first edge of the board, and disposed on a first surface of the board. In addition, each memory chip 90 is mounted on a memory pad region (not shown) disposed on the first surface of the board (i.e., the same surface as tab region 110). Also, discrete devices 97 are mounted on discrete device pad regions (not shown), which are also disposed on the first surface of the board.

Additionally, in the embodiments of the invention described with reference to FIGS. 8 through 13, discrete devices 97 are divided into groups of discrete devices 97, wherein each group of discrete devices 97 corresponds to only one memory pad region and the memory chip 90 disposed thereon, and each memory pad region and the memory chip 90 disposed thereon corresponds to only one group of discrete devices 97. Thus, each group of discrete devices 97 has one corresponding memory pad region (and memory chip 90), and each memory pad region (and memory chip 90) has one corresponding group of discrete devices 97. When discrete devices 97 or a group of discrete devices 97 is referred to herein as corresponding to a memory chip 90, the discrete devices 97 or group of discrete devices 97 likewise correspond to the memory pad region 195 on which the memory chip 90 is mounted.

FIG. 8 is a plan view showing a memory module in accordance with an embodiment of the invention. In the embodiment illustrated in FIG. 8, the board of the memory module is a board 200 (i.e., a main body of a board 200), and each group of discrete devices 97 is disposed between its corresponding memory chip 90 and tab region 110. In addition, buffer regions 201 are disposed in the upper region (NP of FIG. 4) of board 200. That is, each buffer region 201 is disposed adjacent to a second edge of board 200 opposite the first edge. No discrete device 97 is disposed in any of first buffer regions 201. First buffer regions 201 are adapted to separate memory chips 90 from the second edge of board 200. Accordingly, it may be possible to mount memory chips 90 having various sizes on the PCB illustrated in FIG. 8.

FIG. 9 is a plan view showing a memory module in accordance with another embodiment of the invention. In the embodiment illustrated in FIG. 9, the board of the memory module is a board 300, and each group of discrete devices 97 is disposed in the upper region (NP of FIG. 4) of board 300. That is, each group of discrete devices 97 is disposed adjacent to a second edge of board 300 opposite the first edge of board 300. The memory module illustrated in FIG. 9 also comprises buffer regions 302. Each buffer region 302 is disposed between one of memory chips 90 and tab region 110. Buffer regions 302 area adapted to separate memory chips 90 from tab region 110. Accordingly, it may be possible to mount memory chips 90 having various sizes on the PCB illustrated in FIG. 9.

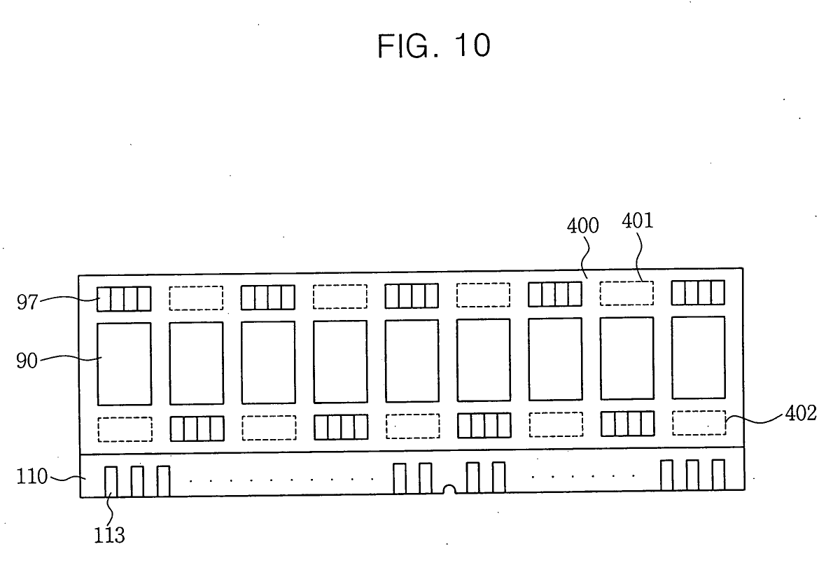

FIG. 10 is a plan view showing a memory module in accordance with yet another embodiment of the invention. In the embodiment illustrated in FIG. 10, the board of the memory module is a board 400, and memory chips 90 are divided into a first plurality of memory chips 90 and a second plurality of memory chips 90. In addition, the groups of discrete devices 97 are divided into a first plurality of groups of discrete devices 97 and a second plurality of groups of discrete devices 97. Each group of the first plurality of groups of discrete devices 97 is disposed between tab region 110 and a corresponding memory chip 90 of the first plurality of memory chips 90. Additionally, first buffer regions 401 are disposed adjacent to a second edge of board 400 opposite the first edge of board 400 and are each disposed adjacent to a memory chip 90 of the first plurality of memory chips 90. That is, first buffer regions 401 are disposed in the upper region (NP of FIG. 4) of board 400.

In addition, each group of the second plurality of groups of discrete devices 97 is disposed between the second edge of board 400 and a corresponding memory chip 90 of the second plurality of memory chips 90. Additionally, each second buffer region 402 of a plurality of second buffer regions 402 is disposed between a memory chip 90 of the second plurality of memory chips 90 and tab region 110.

First and second buffer regions 401 and 402 are adapted to separate memory chips 90 from the second edge of main body 400 and tab region 110, respectively. Accordingly, it may be possible to mount memory chips 90 having various sizes on the PCB illustrated in FIG. 10.

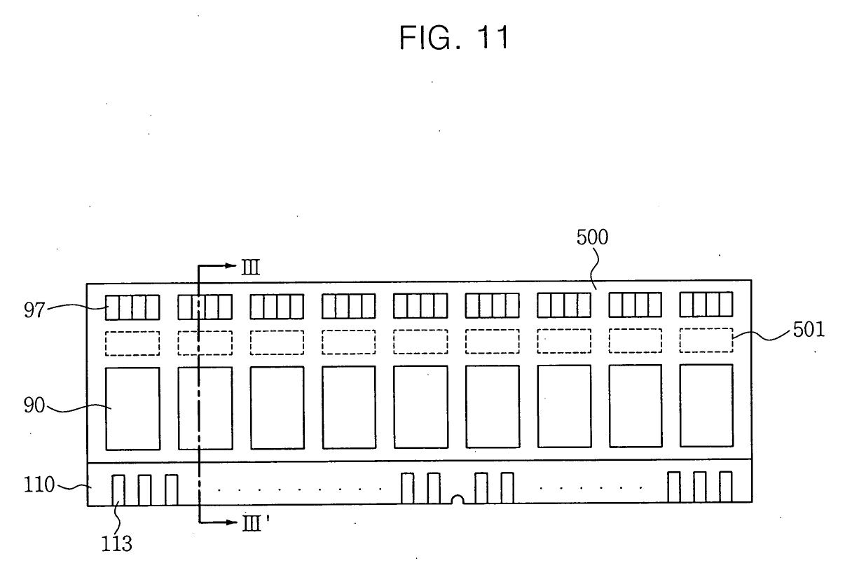

FIG. 11 is a plan view showing a memory module in accordance with still another embodiment of the invention. In the embodiment illustrated in FIG. 11, the board of the memory module is a board 500, and each group of discrete devices 97 is disposed adjacent to a second edge of board 500 opposite the first edge of board 500. In addition, the memory module of the embodiment illustrated in FIG. 11 comprises buffer regions 501, wherein each buffer region 501 is disposed between a group of discrete devices 97 and the memory chip 90 corresponding to that group of discrete devices 97. First buffer regions 501 are adapted to separate each memory chip 90 from its corresponding group of discrete devices 97. Accordingly, it may be possible to mount memory chips 90 having various sizes on the PCB illustrated in FIG. 11.

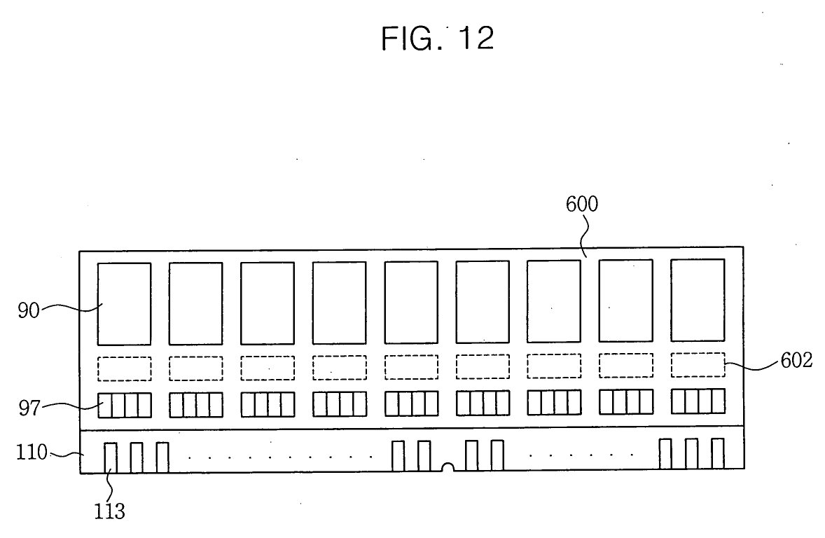

FIG. 12 is a plan view showing a memory module in accordance with yet another embodiment of the invention. In the embodiment illustrated in FIG. 12, the board of the memory module is a board 600, and each group of discrete devices 97 is disposed between its corresponding memory chip 90 and tab region 110. In addition, a buffer region 602 of a plurality of buffer regions 602 is disposed between each group of discrete devices 97 and its corresponding memory chip 90. Buffer regions 602 are adapted to separate memory chips 90 from their corresponding groups of discrete devices 97. Accordingly, it may be possible to mount memory chips 90 having various sizes on the PCB.

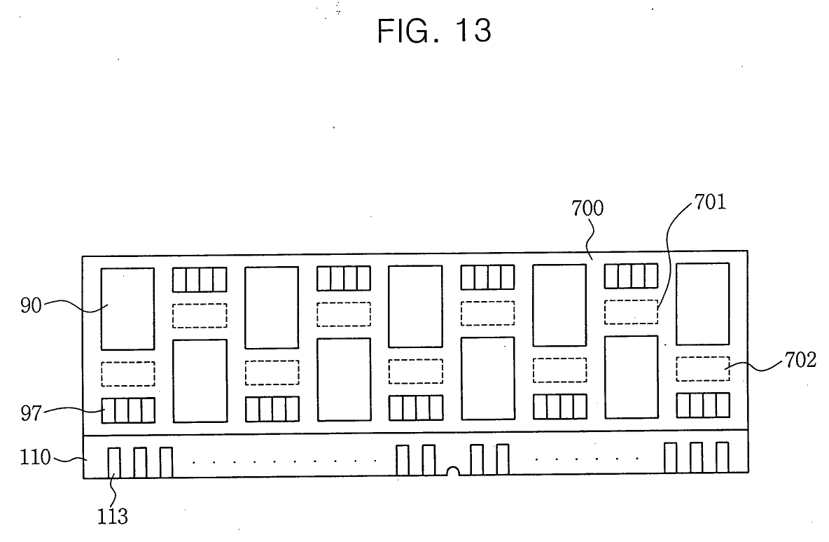

FIG. 13 is a plan view showing a memory module in accordance with another embodiment of the invention. In the embodiment illustrated in FIG. 13, the board of the memory module is a board 700 (i.e., a main body of a board 700), and memory chips 90 are divided into a first plurality of memory chips 90 and a second plurality of memory chips 90. In addition, the groups of discrete devices are divided into a first plurality of groups of discrete devices 97 and a second plurality of groups of discrete devices 97. The memory chips 90 may be disposed in a “zigzag” pattern. Each memory chip 90 of the first plurality of memory chips 90 is disposed adjacent to tab region 110. In addition, each group of the first plurality of groups of discrete devices 97 is disposed between the second edge of board 700 opposite the first edge of board 700 and a corresponding memory chip 90 of the first plurality of memory chips 90. In addition, first buffer regions 701 are respectively disposed between each group of the first plurality of groups of discrete devices 97 and the corresponding memory chip 90 of the first plurality of memory chips 90.

Additionally, each memory chip 90 of the second plurality of memory chips 90 is disposed adjacent to the second edge of board 700. In addition, each group of the second plurality of groups of discrete devices 97 is disposed between tab region 110 and a corresponding memory chip 90 of the second plurality of memory chips 90. In addition, second buffer regions 702 are respectively disposed between each group of the second plurality of groups of discrete devices 97 and the corresponding memory chip 90 of the first plurality of memory chips 90.

First and second buffer regions 701 and 702 are adapted to separate memory chips 90 from their corresponding group of discrete devices 97. Accordingly, it may be possible to mount memory chips 90 having various sizes on the PCB.

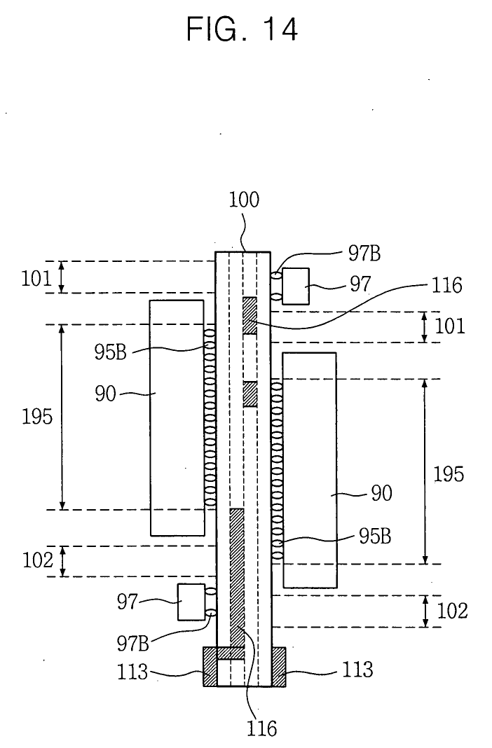

FIG. 14 is a cross-sectional view of a memory module in accordance with another embodiment of the invention. The embodiment illustrated in FIG. 14 is similar to the embodiment illustrated in FIGS. 2 to 6, except for the arrangement of elements and regions on the first surface of the board (which is the right side of the board as illustrated in FIG. 14).

In the embodiment illustrated in FIG. 14, the memory module comprises a board 100, a first plurality of memory chips 90 mounted on the first surface of board 100, a second plurality of memory chips 90 mounted on a second surface of board 100 opposite the first surface, a first plurality of discrete devices 97 mounted on the first surface of board 100, and a second plurality of discrete devices 97 mounted on the second surface of board 100. In addition, the first surface of board 100 comprises a first tab region 110 (not shown) comprising a first plurality of tabs 113, and the second surface of board 100 comprises a second tab region 110 (not shown) comprising a second plurality of tabs 113.

Additionally, the arrangement of elements and regions on the second surface of board 100 (which is the left side of board 100 as illustrated in FIG. 14) is the same as the arrangement of elements and regions on each of the first and second surfaces of board 100 of the embodiment illustrated in FIGS. 2 to 6.

On the first surface of the memory module illustrated in FIG. 14, a discrete device pad region (not shown) is disposed adjacent to a second edge of board 100 opposite the first edge of board 100, and discrete devices 97 of the first plurality of discrete devices 97 are attached to the discrete device pad region. That is, discrete devices 97 of the first plurality of discrete devices 97 disposed on the first surface of board 100 are disposed adjacent to the second edge of board 100.

In addition, memory chips 90 of the first plurality of memory chips 90 disposed on the first surface of board 100 are disposed between discrete devices 97 of the first plurality of discrete devices 97 and first tab region 110. That is, memory pad regions 195 (see FIG. 4) are disposed on board 100 between discrete devices 97 of the first plurality of discrete devices 97 and first tab region 110. Additionally, first buffer regions 101 are respectively disposed between groups of discrete devices 97 of the first plurality of discrete devices 97 and memory chips 90 of the first plurality of memory chips 90. Also, second buffer regions 102 are respectively disposed between memory chips 90 of the first plurality of memory chips 90 and first tab region 110.

In the embodiment illustrated in FIG. 14, the memory module comprises a PCB comprising board 100, tabs 113, internal interconnections 116, memory pad regions 195, and discrete device pad regions. Also, first and second buffer regions 101 and 102 are disposed on each of the first and second surfaces of board 100.

On the first surface of board 100, first buffer regions 101 separate memory pad regions 195 from corresponding groups of discrete devices 97 and second buffer regions 102 separate memory pad regions 195 from first tab region 110. On the second surface of board 100, first buffer regions 101 separate memory pad regions 195 from the second edge of board 100 and second buffer regions 102 separate memory pad regions 195 from corresponding groups of discrete devices 97. Accordingly, it may be possible to mount memory chips 90 on the PCB even when the respective areas of the bottoms of memory chips 90 are greater than the area of each memory pad region 195. That is, the PCB having first buffer regions 101 and second buffer regions 102 may provide a margin sufficient to allow memory chips 90 having different sizes to be mounted on the PCB.

In addition, the arrangement of memory chips 90 on the first surface of board 100 and the arrangement of memory chips 90 on the second surface of board 100 are asymmetrical with respect to a plane passing through the center of board 100 and substantially parallel to the first and second surfaces. That is, memory pad regions 195 disposed on the first surface of board 100 are each separated from the first edge of board 100 by a first distance and memory pad regions 195 disposed on the second surface of board 100 are each separated from the first edge of board 100 by a second distance different than the first distance. Therefore, the memory module in accordance with the embodiment illustrated in FIG. 14 may have a structure that effectively emits heat generated from memory chips 90.

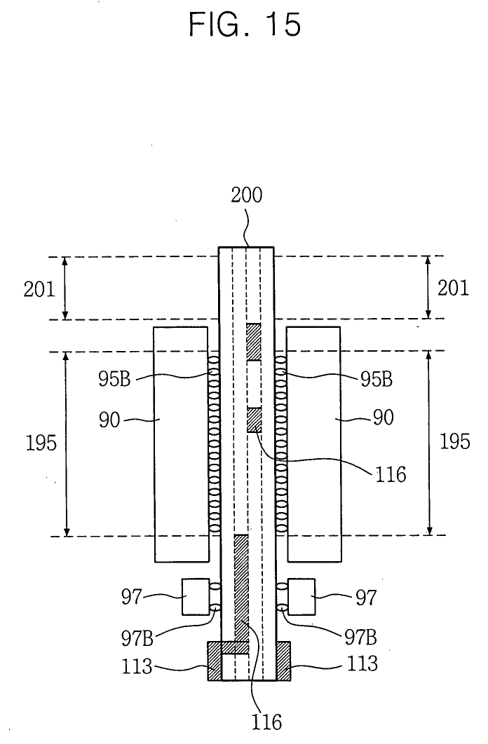

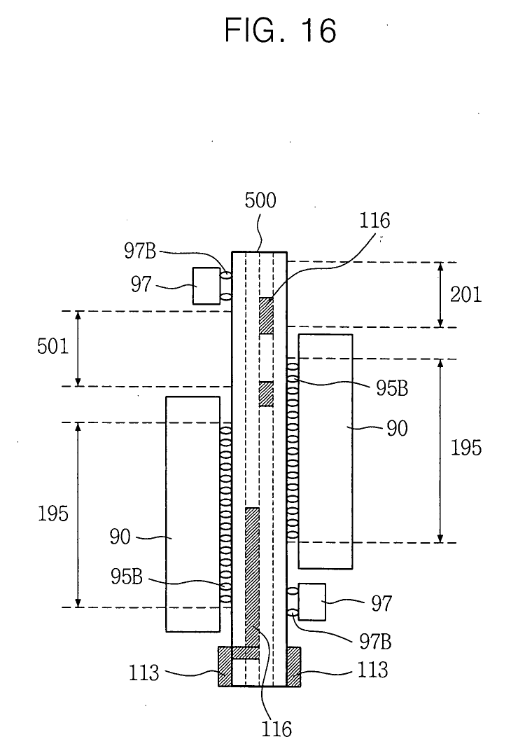

FIG. 15 is a cross-sectional view of the memory module of FIG. 8 taken along line II-II′ of FIG. 8.

In the embodiment illustrated in FIGS. 8 and 15, the memory module comprises a board 200. In addition, the memory module comprises memory chips 90 and groups of discrete devices 97 disposed on a first surface of board 200 (which is the right side of board 200 as illustrated in FIG. 15). The memory module also comprises memory chips 90 and groups of discrete devices 97 disposed on a second surface of board 200 opposite the first surface. The second surface of board 200 is the left side of board 200 as illustrated in FIG. 15. In addition, a first tab region 110 comprising tabs 113 is disposed on the first surface of board 200 and a second tab region 110 comprising tabs 113 is disposed on the second surface of board 200. First tab region 110 is disposed adjacent to a first edge of board 200, and second tab region 110 is also disposed adjacent to the first edge of board 200. Also, on each of the first and second surfaces of the board 200, the memory chips 90 are mounted on memory pad regions 195, respectively, and discrete devices 97 are mounted on discrete device pad regions (not shown).

In addition, the arrangement of elements and regions on each of the first and second surfaces of board 200 is the same as the arrangement of elements and regions on the first surface of board 200 of the memory module illustrated in FIG. 8.

In the embodiment illustrated in FIGS. 8 and 15, the memory module comprises a PCB comprising board 200, tabs 113, internal interconnections 116, memory pad regions 195, and discrete device pad regions.

On each of the first and second surfaces, groups of discrete devices 97 are each disposed between a corresponding memory chip 90 and tab region 110, and buffer regions 201 are disposed in the upper region NP of board 200 (see FIG. 4). Buffer regions 201 are adapted to separate memory chips 90 from the second edge of board 200. Accordingly, it may be possible to mount memory chips 90 on the PCB even when the memory chips 90 extend past the boundaries of the respective memory pad regions 195 on which they are mounted.

In addition, the memory module in accordance with the embodiment illustrated in FIG. 15 has a structure in which memory chips 90 and discrete devices 97 are disposed relatively close to tabs 113 compared to the conventional art. Therefore, the memory module may have good electrical characteristics such as low noise and fast response speed.

Further, buffer regions 201 may be omitted. When buffer regions 201 are omitted, the size of board 200 may be reduced in accordance with the size of buffer regions 201. That is, a board 200 that is shorter than the board 200 illustrated in FIGS. 8 and 15 in a direction substantially perpendicular to the first edge of board 200 may be produced, thereby implementing a memory module having a relatively low profile.

FIG. 16 is a cross-sectional view of a memory module in accordance with another embodiment of the invention. In the embodiment illustrated in FIG. 11, the arrangement of elements and regions on a second surface of board 500 opposite the first surface is the same as the arrangement of elements and regions on the first surface of board 500. The embodiment illustrated in FIG. 16 is similar to the embodiment illustrated in FIG. 11, except for the arrangement of elements and regions on the first surface of board 500 (which is on the right side of board 500 as illustrated in FIG. 16).

In the embodiment illustrated in FIG. 16, the memory module comprises board 500, a first tab region 110 comprising tabs 113 is disposed on the first surface and disposed adjacent to a first edge of board 500, and a second tab region 110 comprising tabs 113 is disposed on the second surface and disposed adjacent to the first edge of board 500.

The second surface of board 500 of the memory module of FIG. 16 has substantially the same arrangement of elements and regions (i.e., the same structure) as either of the first and second surfaces of the memory module illustrated in FIG. 11. On each of the first and second surfaces of board 500 of FIG. 16, memory chips 90 are mounted on memory pad regions 195, respectively, and discrete devices 97 are mounted on discrete device pad regions (not shown). On the second surface of board 500 of FIG. 16, discrete devices 97 are disposed adjacent to a second edge of board 500 opposite the first edge. In addition, buffer regions 501 are disposed between discrete devices 97 and memory chips 90. Buffer regions 501 are adapted to separate memory chips 90 from discrete devices 97 on the second surface of board 500.

The first surface of board 500 of FIG. 16 has substantially the same arrangement of elements and regions (i.e., the same structure) as the memory module illustrated in FIG. 8. First tab region 110 comprising a plurality of tabs 113 is disposed adjacent to the first edge of board 500. On the first surface of board 500, each group of discrete devices 97 is disposed between a corresponding memory chip 90 and first tab region 110. In addition, buffer region 201 in disposed in the upper region (NP of FIG. 4) of board 500. Buffer region 201 is adapted to separate memory chips 90 from the second edge of board 500. Accordingly, a memory chip 90 can be mounted on the PCB even when the memory chip 90 extends past the boundaries of the memory pad region 195 on which it is mounted.

Embodiments of the invention provide a memory module that comprises a PCB on which memory chips and discrete devices are mounted. The PCB comprises a board, tabs, internal interconnections, at least one memory pad region, and at least one discrete device pad region. In addition, the memory module comprises at least one group of discrete devices disposed on only one side of a corresponding memory pad region. In accordance with embodiments of the invention, a memory chip may be mounted on the PCB even when the area of the bottom of the chip is larger than the area of a memory pad region. Thus, in accordance with embodiments of the invention, relatively larger memory chips may be mounted on a PCB without increasing the size of the PCB.

Although embodiments of the invention have been described herein, various changes in form and details may be made to the embodiments by those of ordinary skill in the art without departing from the scope of the invention as set forth in the accompanying claims.

What is claimed is:

1. A memory module comprising:
a plurality of tabs disposed adjacent to a first edge of and on a first surface of a board;
a memory pad region disposed on the first surface and comprising memory chip pads, wherein each memory chip pad is electrically connected to at least one of the plurality of tabs; and,
discrete devices corresponding to the memory pad region, wherein the discrete devices corresponding to the memory pad region are disposed on only one side of the memory pad region,
wherein each of the discrete devices is electrically connected to at least one of the plurality of tabs and at least one of the memory chip pads.

2. The memory module of claim 1, wherein the memory pad region is separated from the discrete devices corresponding to the memory pad region by a buffer region.

3. The memory module of claim 1, wherein the memory pad region is separated from a second edge of the board opposite the first edge by a buffer region.

4. The memory module of claim 1, wherein the discrete devices corresponding to the memory pad region are disposed between the plurality of tabs and the memory pad region.

5. The memory module of claim 1, wherein the discrete devices corresponding to the memory pad region are disposed adjacent to a second edge of the board opposite the first edge.

6. The memory module of claim 1, further comprising:
a memory chip mounted on the memory pad region.

7. The memory module of claim 1, wherein the memory chip pads are arranged to correspond to a plurality of terminals disposed in a terminal region of the memory chip.

8. The memory module of claim 1, wherein each of the discrete devices is a device selected from the group consisting of a resistor, a capacitor, an inductor, a register, a programmable device, and a non-volatile memory device.

9. A memory module comprising:
a plurality of tabs disposed adjacent to a first edge of and on a first surface of a board;
a plurality of memory pad regions disposed on the first surface and separated from one another along a first axis substantially parallel to the first edge of the board, wherein each memory pad region comprises memory chip pads and each memory chip pad is electrically connected to at least one of the plurality of tabs; and,
a plurality of groups of discrete devices, wherein each group of discrete devices corresponds to one of the memory pad regions, and, for each of at least one of the memory pad regions, the discrete devices of the group of discrete devices corresponding to the memory pad region are disposed on only one side of the memory pad region,
wherein each of the discrete devices is electrically connected to at least one of the plurality of tabs and at least on of the memory chip pads.

10. The memory module of claim 9, wherein the memory pad regions are disposed in a line.

11. The memory module of claim 9, wherein:
a first memory pad region of the memory pad regions is disposed adjacent to a second edge of the board opposite the first edge;
a second memory pad region of the memory pad regions is disposed adjacent to the tabs;
a first group of discrete devices corresponding to the first memory pad region is disposed between the tabs and the first memory pad region; and,
a second group of discrete devices corresponding to the second memory pad region is disposed adjacent to the second edge of the board.

12. The memory module of claim 11, wherein the first group of discrete devices is separated from the first memory pad region by a first buffer region and the second group of discrete devices is separated from the second memory pad region by a second buffer region.

13. The memory module of claim 9, wherein each group of discrete devices is disposed between adjacent ones of the plurality of tabs and a corresponding one of plurality of memory pad regions.

14. The memory module of claim 9, wherein each group of discrete devices is disposed adjacent to a second edge of the board opposite the first edge.

15. The memory module of claim 9, wherein each memory pad region is separated from one of the groups of discrete devices by a buffer region.

16. The memory module of claim 9, wherein each memory pad region is separated from a second edge of the board opposite the first edge by a buffer region.

17. A memory module comprising:
a plurality of first tabs disposed adjacent to a first edge of and on a first surface of a board;
a plurality of second tabs disposed adjacent to the first edge of the board and disposed on a second surface of the board opposite the first surface;
a plurality of first memory pad regions disposed on the first surface and separated from one another along a first axis substantially parallel to the first edge of the board, wherein each first memory pad region comprises first memory chip pads and each first memory chip pad is electrically connected to at least one of the first tabs;
a plurality of second memory pad regions disposed on the second surface;
a plurality of groups of first discrete devices disposed on the first surface, wherein each group of first discrete devices correspond to one of the first memory pad regions, and, for each of at least one of the first memory pad regions, the first discrete devices of the group of first discrete devices corresponding to the first memory pad region is disposed on only one side of the first memory pad region; and,
a plurality of groups of second discrete devices disposed on the second surface,
wherein each of the first discrete devices is electrically connected to at least one of the first tabs and at least one of the first memory chip pads.

18. The memory module of claim 17, wherein one of the first memory pad regions is separated from the first edge of the board by a first distance and one of the second memory pad regions is separated from the first edge by a second distance different than the first distance.

19. The memory module of claim 18, wherein the first discrete devices are disposed adjacent to a second edge of the board opposite the first edge, and the second discrete devices are disposed between the second tabs and the second memory pad regions.

20. The memory module of claim 9, further comprising memory chips, wherein each memory chip is mounted on one of the first memory pad regions or one of the second memory pad regions.

21. The memory module of claim 20, wherein at least one of the memory chips is a volatile memory device.

22. The memory module of claim 9, wherein each of the first and second discrete devices is a device selected from the group consisting of a resistor, a capacitor, an inductor, a register, a programmable device, and a non-volatile memory device.
